(19) United States
(12) Patent Application Publication
(10) Pub. No.: US 2017/0170357 A1
(43) Pub. Date: Jun. 15, 2017

(54) METHOD FOR PREVENTING AN ELECTRICAL SHORTAGE IN A SEMICONDUCTOR LAYER STACK, THIN SUBSTRATE CPV CELL, AND SOLAR CELL ASSEMBLY

(71) Applicant: Saint-Augustin Canada Electric Inc., Saint-Augustin (CA)

(72) Inventors: Rainer Krause, Mainz-Kostheim (DE); Bruno Ghyselen, Seyssinet (FR); Chantal Arena, Mesa, AZ (US)

(21) Appl. No.: 15/443,386

(22) Filed: Feb. 27, 2017

Related U.S. Application Data
(62) Division of application No. 14/359,164, filed on May 19, 2014.

(30) Foreign Application Priority Data
Nov. 25, 2011 (FR) 1160802

(51) Int. Cl. H01L 31/18; H01L 31/052; H01L 31/02

(52) U.S. Cl. CPC H01L 31/186; H01L 31/02008; H01L 31/052

(57) ABSTRACT

The invention relates to a method for preventing an electrical shortage between at least two layers of a semiconductor layer stack attached by the surface of one of its layers to a substrate via a conductive adhesive by providing an isolating layer on the side walls of the stack or by removing excess material after attaching the stack to the substrate. The invention also relates to a thin substrate CPV cell and to a solar cell assembly.

### CROSS-REFERENCE TO RELATED APPLICATIONS

This application is a divisional of U.S. patent application Ser. No. 14/359,164, filed May 19, 2014, pending, which application is a national phase entry under 35 U.S.C. §371 of International Patent Application PCT/IB2012/002350, filed Nov. 12, 2012, designating the United States of America and published in English as International Patent Publication WO 2013/076543 A2 on May 30, 2013, which claims the benefit under Article 8 of the Patent Cooperation Treaty and under 35 U.S.C. §119(e) to French Patent Application Serial No. 1160802, filed Nov. 25, 2011, the disclosure of each of which is hereby incorporated herein in its entirety by this reference.

### TECHNICAL FIELD

The invention relates to a method for preventing an electrical shortage between at least two layers of a semiconductor layer stack attached to a substrate via a conductive adhesive, in particular, when the semiconductor layer stack is a thin substrate concentrated photovoltaic (CPV) cell and the substrate is a heat sink. The invention also relates to a thin substrate CPV cell and to a solar cell assembly (SCA).

### BACKGROUND

Solar cell assemblies (SCA) with concentrated photovoltaic (CPV) cells typically comprise a semiconductor layer stack forming the CPV cell, which is attached by the surface of one of its layers to a heat sink by means of an electrically conductive adhesive paste such as a thermal contact paste, e.g., a silver paste material, as described in US 2011/0048501 A1 and US 2008/0230109 A1.

The production costs of such solar cell assemblies can be reduced by using CPV cells comprising a thin substrate material, for example, with a thickness typically inferior to about 100 μm, also called thin substrate CPV cells. However, when using such thin substrate CPV cells, assembling the SCA can have the effect of electrically shortening the bottom junctions of the semiconductor layer stack forming the thin substrate CPV cell. The reason for this shortage is that the conductive adhesive paste provided between the surfaces of the thin substrate CPV cell and the heat sink, respectively, overflows, such that the surplus of conductive adhesive paste is in contact with at least one of the side walls of the semiconductor layer stack forming the CPV cell. In particular, if the layer of semiconductor substrate material forming the outermost layer of the CPV cell that is attached to the heat sink is thinner than the thickness of the surplus of conductive adhesive paste, an electrical shortage happens between the layers of the CPV cell that are brought in contact by this surplus of adhesive paste. Therefore, CPV cells comprising a semiconductor substrate material with a typical thickness of about 170 μm to 200 μm or more are used to prevent such electrical shortages.

However, using CPV cells with thinner substrate materials is advantageous for SCA, as thin substrates present not only lower costs, but also a lower resistance and thus better thermal conditions for the SCA.

### DISCLOSURE

It is, therefore, the object of the present invention to improve the current assembly process such that, in the case of a SCA comprising a thin substrate CPV cell, the occurrence of electrical shortages can be reduced or even prevented.

The object of the invention is achieved with the method described herein. The inventive method for preventing an electrical shortage between at least two layers of a semiconductor layer stack attached by the surface of one of its layers to a substrate via a conductive adhesive comprises the step of: step a) providing a semiconductor layer stack comprising two main surfaces corresponding to the free surfaces of the outermost layers and side walls connecting the two main surfaces; step b) attaching a substrate to the semiconductor layer stack via a conductive adhesive provided either on one of the main surfaces of the semiconductor layer stack or on the substrate; and step c) at least partially removing excess material of the conductive adhesive from at least one of the side walls adjacent to the main surface of the semiconductor layer stack attached to the substrate.

The inventive method advantageously prevents an electrical shortage in already assembled structures for which the surplus of conductive adhesive can cover at least two layers of at least one of the side walls of the semiconductor layer stack. In particular, when the semiconductor layer stack is a concentrated photovoltaic (CPV) cell or a thin substrate CPV cell, and when the substrate is a heat sink, the inventive method prevents an electrical shortage in the solar cell assembly (SCA) by removing the surplus of adhesive paste, e.g., silver paste, from the bottom edges of the CPV cell. Advantageously, already existing assembly processes do not require substantial changes as the step of removing the surplus of conductive adhesive can be added at the end of the existing process.

Preferably, the excess material can be removed by a thermal treatment, in particular, by laser ablation technique.

A thermal treatment, in particular, using laser ablation, has the advantage of removing the surplus of adhesive material with high precision, while keeping the assembled structure intact. Optimal results have been observed when removing a surplus of thermal adhesive paste, in particular, silver paste, in a SCA comprising a thin substrate CPV cell in order to prevent electrical shortages between layers of the CPV cell when attached to a heat sink.

The object of the invention is also achieved with the method described herein. The inventive method for preventing an electrical shortage between at least two layers of a semiconductor layer stack attached by the surface of one of its layers to a substrate via a conductive adhesive comprises the step of: step a) providing a semiconductor layer stack comprising two main surfaces corresponding to the free surfaces of the outermost layers and side walls connecting the two main surfaces; step b) at least partially providing an isolating layer on at least one of the side walls of the semiconductor layer stack; and step c) attaching a substrate to the semiconductor layer stack via a conductive adhesive provided either on one of the main surfaces of the semiconductor layer stack or on the substrate.

The inventive method disclosed herein has the advantage that at least one of the side walls of the semiconductor layer stack is at least partially electrically isolated toward the environment before the attachment step. Hence, when performing the attachment of the semiconductor layer stack to the substrate, at least one of the side walls of the semiconductor layer stack is at least partially isolated from the adhesive conductive, thus preventing an electrical shortage. The inventive method is well adapted for preventing electrical shortages when attaching a thin substrate CPV cell to a heat sink by means of a conductive adhesive such as silver paste because the side walls of the CPV cell can be at least partially isolated from the silver paste.

Preferably, in step b, the isolating layer can be at least partially provided on the at least one side wall toward the main surface of the semiconductor layer stack that will be attached to the substrate in step c.

Following this preferred variant of the inventive method, the isolation can be selectively provided more precisely on the region of the at least one side wall of the semiconductor layer stack that is toward the surface that will be attached to the substrate in the attachment step. Hence, an advantage is that an electrical isolation can be selectively provided on the regions of the side walls of the semiconductor layer stack that are more affected by the surplus of conductive adhesive. In the case of a SCA, at least the bottom layers of the thin substrate CPV cell between which an electrical shortage can occur due to excessive conductive adhesive can be isolated, thus preventing the shortage.

Advantageously, the isolating layer can cover a plurality of layers in the semiconductor layer stack toward the main surface where the attachment will occur.

An advantage of this variant of the inventive method is that the isolation can be provided even more selectively on the side walls of as many layers as needed, depending on the surplus of adhesive, so that an electrical shortage between two or more layers of the semiconductor layer stack is prevented optimally. In the case of SCAs, optimal prevention of electrical shortages between layers of the thin substrate CPV cell is achieved, as the number of layers that require isolation can be selectively adjusted depending on the quantity of adhesive conductive, e.g., silver paste.

In a preferred variant of an embodiment of the inventive method disclosed herein, the isolating layer can be deposited by thermal spraying, in particular, by plasma spraying.

Thermal spraying, in particular, plasma spraying, can be used for preventing electrical shortages, in particular, in the context of SCAs, where bottom layers of a thin substrate CPV cell that will be attached to a heat sink need to be isolated from the adhesive, e.g., the silver paste that will be used for the attachment. A gas nozzle with, e.g., SiOC gas, or a SiN and TiO based gas, can be combined with a laser beam to deposit a plasma on the lower edge of the thin substrate CPV cell, thus isolating the lower cell edge and preventing it from electrical shortage by the conductive adhesive, e.g., the silver paste, at the assembly process. Other techniques could be used as well, such as dip or stamping technology, as well as sputter or evaporation, or even printing technology, depending on the costs and/or accuracy and/or repetitiveness that need to be achieved.

In a preferred variant of embodiments of the inventive methods, the semiconductor layer stack can be a photovoltaic cell, in particular, a thin substrate concentrated photovoltaic (CPV) cell, the substrate can be a heat sink and the conductive adhesive can be thermal contact paste, in particular, silver paste.

The inventive methods disclosed herein are advantageous for solar cell assemblies comprising a thin substrate CPV cell attached to a heat sink by silver paste, for which the surplus of silver paste may produce a shortage in the lower junctions of the thin substrate CPV cell. Hence, in a preferred embodiment of the inventive methods described herein, the semiconductor layer stack can be a photovoltaic cell, in particular, a thin substrate CPV cell. It is, however, understood that the inventive method also works for other types of photovoltaic cells, in particular, other CPV cells, or any semiconductor layer stack. The thin substrate CPV cell can comprise a substrate layer of a few nm to several tens of μm, and can comprise, e.g., CdTe, Si, GaAs, or an organic polymer. In a preferred embodiment, the substrate can be a heat sink. The heat sink material can be, e.g., one of copper or aluminum, or any other metal compound used for heat dissipating means. It is also understood that the substrate can be another heat dissipating means or another semiconductor layer stack or a structure comprising a second semiconductor layer that needs to be attached to the semiconductor layer stack, e.g., the thin substrate CPV cell, by means of a conductive adhesive. The conductive adhesive can be silver paste or any other electrically conductive adhesive paste or the like.

In a preferred variant of the inventive method described herein, step b can further comprise: step i) applying an etch mask to the main surface of the semiconductor layer stack that will be attached to the substrate in step c; step ii) etching at least partially into the unmasked area of the masked main surface of the semiconductor layer stack to obtain at least one etched hole comprising at least one side wall adjacent to the masked main surface of the semiconductor layer stack; step iii) at least partially covering with a passivation material the at least one side wall of the at least one etched hole adjacent to the masked main surface of the semiconductor layer stack; and step iv) at least partially filling with an isolating material the at least one etched hole comprising at least one side wall at least partially covered with a passivation material and adjacent to the masked main surface.

This variant of the inventive method disclosed herein, has the advantage that it can be used, e.g., during the production of the semiconductor layer stack, directly at the wafer level. Thus, according to a preferred embodiment, the inventive method can advantageously be adapted to the industrial production of solar cells, so that the wafers out of which the thin substrate CPV cells are formed already comprise isolating means in order to prevent electrical shortages when the CPV cells are assembled to the heat sinks in a further production step.

In a further preferred variant of the inventive method, step b can further comprise: step v) cutting through the at least partially filled at least one etched hole to obtain at least one semiconductor layer stack with two main surfaces corresponding to the free surfaces of the outermost layers and side walls connecting the two main surfaces, wherein at least one side wall at least partially comprises an isolating layer toward the main surface where the attachment will occur.

A preferred embodiment of this variant of the inventive method can be particularly advantageous for SCAs, as a plurality of individual thin substrate CPV cells with side walls comprising isolating layers toward the surface where the attachment to the heat sink via a conductive adhesive will occur can be fabricated simultaneously from an initial wafer, thus improving the assembly process.

The object of the invention is also achieved with the semiconductor layer stack described herein, wherein the inventive semiconductor layer stack forms a photovoltaic cell, in particular, a thin substrate concentrated photovoltaic (CPV) cell, comprising: two main surfaces corresponding to the free surfaces of the outermost layers of the semiconductor layer stack; and side walls connecting the two main surfaces; characterized in that at least one side wall of the semiconductor layer stack is at least partially covered by an isolating layer.

The inventive semiconductor layer stack, in particular, the inventive thin substrate CPV cell, advantageously prevents an electrical shortage in a SCA in which it is attached to a heat sink by means of an electrically conductive adhesive because the isolating layer at least partially isolates one side wall of the CPV cell from the surplus of conductive adhesive.

Advantageously, the isolating layer can at least partially cover the at least one side wall toward one of the main surfaces of the semiconductor layer stack.

Thus, the inventive semiconductor layer stack is particularly adapted for selectively preventing an electrical shortage in a SCA because the isolation is specifically and selectively provided on the regions of the side walls of the CPV cell that will be in contact with the conductive adhesive.

The object of the invention is also achieved with the solar cell assembly (SCA) disclosed herein, wherein the SCA comprises: a semiconductor layer stack forming a thin substrate concentrated photovoltaic (CPV) cell attached to a heat sink by a thermal contact paste, wherein the thin substrate CPV cell comprises two main surfaces corresponding to free surfaces of the outermost layers and side walls connecting the two main surfaces; and the heat sink comprises at least one free surface; characterized in that the thermal contact paste is provided only between one main surface of the CPV cell and the at least one free surface of the heat sink.

The inventive SCA has the advantage that the conductive adhesive, in particular, the thermal contact paste, is provided only on the main surface of the CPV cell, in particular, the thin substrate CPV cell, that is attached to the heat sink, but no surplus of conductive adhesive or thermal contact paste is present on any of the side walls of the CPV cell. Thus, the thermal contact paste cannot produce a shortage between at least two layers of the CPV cell.

The object of the invention is also achieved with the solar cell assembly (SCA) described herein, wherein the SCA comprises: a semiconductor layer stack forming a thin substrate concentrated photovoltaic (CPV) cell attached to a heat sink by a thermal contact paste, wherein the thin substrate CPV cell comprises two main surfaces corresponding to free surfaces of the outermost layers and side walls connecting the two main surfaces; and the heat sink comprises at least one free surface; characterized in that the thermal contact paste is provided at least between one main surface of the CPV cell and the at least one free surface of the heat sink; and the side walls of the CPV cell are at least partially covered by an isolating layer toward the main surface attached to the heat sink.

The inventive SCA has the advantage that the side walls of the CPV cell, in particular, the thin substrate CPV cell, are electrically isolated toward the environment. In particular, selected regions of the side walls are electrically isolated from any surplus of conductive adhesive such as thermal contact paste. Thus, no electrical shortage can occur due to the thermal contact paste spilling over the side walls of the thin substrate CPV cell.

### BRIEF DESCRIPTION OF THE DRAWINGS

The invention will be described in more detail in the following, based on advantageous embodiments described in conjugation with the following figures:

FIG. 1 schematically illustrates the inventive method in a first embodiment;

FIG. 2 schematically illustrates the inventive method in a second embodiment; and

FIG. 3 schematically illustrates the inventive method in a third embodiment.

### DETAILED DESCRIPTION

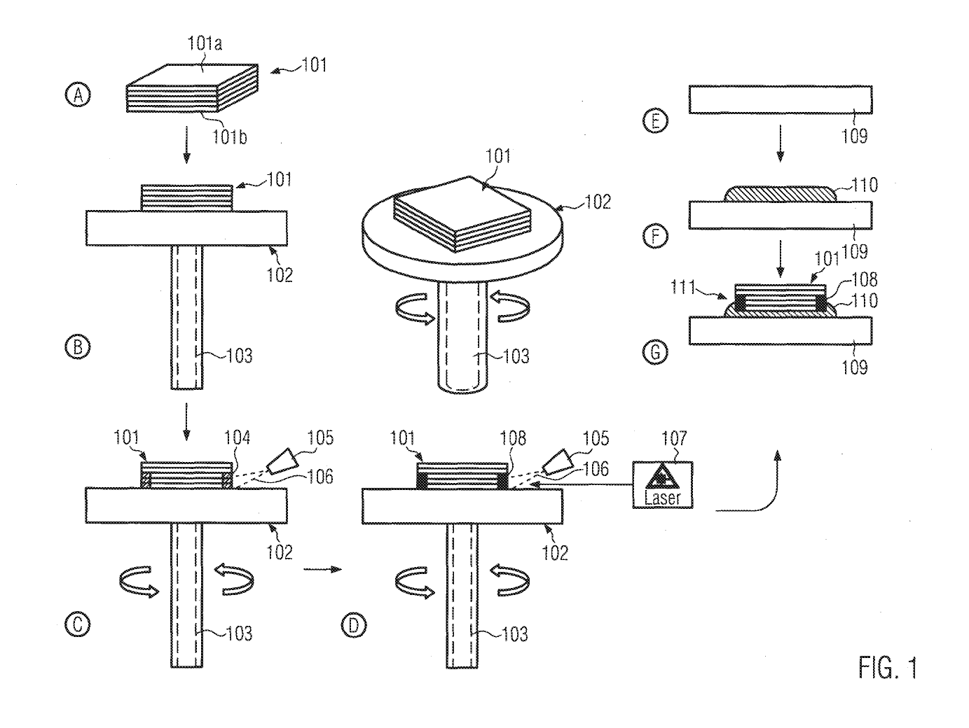

A first embodiment of the inventive method for preventing an electrical shortage between at least two layers of a semiconductor layer stack attached by the surface of one of its layers to a substrate via a conductive adhesive is illustrated in steps A to G of FIG. 1.

According to this embodiment of the inventive method, steps A and B of FIG. 1 illustrate the provision of a semiconductor layer stack 101 comprising two main surfaces 101a, 101b corresponding to the free surfaces of the outermost layers and side walls connecting the two main surfaces 101a, 101b; steps C and D of FIG. 1 at least partially illustrates the provision of an isolating layer 108 on at least one of the side walls 104 of the semiconductor layer stack 101; and steps E to G of FIG. 1 illustrate the attaching of a substrate 109 to the semiconductor layer stack 101 via a conductive adhesive 110 provided either on the one of the main surfaces of the semiconductor layer stack 101 or of the substrate 109 or on both.

In the first embodiment, the semiconductor layer stack 101 can be a thin substrate concentrated photovoltaic (CPV) cell 101, the substrate 109 can be a heat sink 109, and the conductive adhesive 110 can be a silver thermal contact paste 110.

The first embodiment of the inventive method will be described in more detail in the following paragraphs.

Step A of FIG. 1 shows a three-dimensional view of the layer stack 101 of the first embodiment of the inventive method. The layer stack 101 comprises two main surfaces 101a, 101b corresponding to the free surfaces of its outermost layers, and side walls 101c connecting the two main surfaces 101a, 101b. One of the main surfaces, here, the lower one, 101b, of the thin substrate CPV cell 101 corresponds to the surface where the attachment to the heat sink 109 will occur later on, as illustrated in step G of FIG. 1. The thin substrate CPV cell 101 can be a standard CPV cell as known from the art, comprising Ge-based bottom junctions, and various functional epitaxial layers thereon, such as emitter, buffer, window layers and the like, with respective thicknesses in the range of about 100 nm or more. However, the number of layers comprised in the layer stack 101 and their relative thickness are not necessarily representative of real thin substrate CPV cells and are only illustrative.

As illustrated in step B of FIG. 1, in the first embodiment of the inventive method, the layer stack 101 is placed on a rotating table 102 with one of its two main surfaces 101a, 101b facing down on the rotating table 102, preferably the main surface 101b where the attachment to the heat sink 109 by means of the silver paste 110 will occur. Step B of FIG. 1 shows a front 2D view and a 3D view of the layer stack 101 lying on the rotating table 102. In the first embodiment, the rotating table 102 is provided with a vacuum tube 103 so that the layer stack 101 is maintained on the rotating table 102 by a vacuum chuck.

In the first embodiment, an isolating layer 109 is at least partially provided on at least one side wall 104 of the layer stack 101 toward the main surface 101b of the layer stack 101 that will be attached to the heat sink 109. The isolating layer 108 can be provided over all layers or, as illustrated in step C, over only some layers or even only one layer toward the lower main surface 101b.

In this embodiment, the isolating layer 108 is deposited by thermal spraying, in particular, by plasma spraying, as shown in steps C and D of FIG. 1, illustrating the first embodiment. However, other depositing techniques could also be used, such as dip or stamping technology, as well as sputter or evaporation, or even printing technology.

In step C of FIG. 1, a fluid stream 106, in particular, a gaseous stream, is provided by nozzle 105 to provide a material flow, e.g., comprising a SiOC gas or a SiN and TiO based gas, at least toward the lower edge 104 of the thin substrate CPV cell 101, that is, the layers toward the main surface 101b where the attachment to the heat sink 109 will occur. Since the thin substrate CPV cell 101 is maintained on the rotating table 102 by the vacuum chuck created by the vacuum tube 103, only one nozzle 105 needs to be present and, still, a deposition can occur on all side walls of the layer stack 101.

In step D of FIG. 1, typically occurring at the same time as step C, the fluid stream 106 is converted into a plasma stream using a laser 107 focused on the lower edges 104 of the layer stack 101. This then leads to the formation of a deposited isolating layer 108 that partially covers at least one side wall 104 of the layer stack 101. When using SiOC as a gas, an isolating layer 108 of SiOC will be deposited. For the purposes of this invention, a layer thickness in the range of 50 nm up to 200 nm is sufficient and can be achieved within about a 10 nm accuracy and reasonable low process lead time (in the minute range).

In the first embodiment, the rotating table 102 allows for depositing the isolating layer 108 all around the layer stack 101. Depending on the adjustment of the laser, the deposited isolating layer 108 will be present on one or more layers toward the lower edges 104 of the layer stack 101, toward the main surface 101b, or even over the entire side walls of the layer stack 101.

In steps E to G of FIG. 1, the attachment step of the layer stack 101 to a substrate 109 via the conductive adhesive 110 of the inventive method of the first embodiment is illustrated. As illustrated in the example of the first embodiment, this leads to the attachment of a CPV cell to a heat sink via a silver thermal contact paste.

In step E of FIG. 1, the substrate 109 is provided for realizing the solar cell assembly (SCA), and in step F of FIG. 1, the conductive adhesive 110 is provided on the surface of the substrate 109 that will be attached to the layer stack 101 with the isolating layer 108 provided toward the main surface 101b where the attachment will occur. According to a variant, the conductive adhesive could also be provided on the layer stack 101 or on both the layer stack 101 and the substrate 109.

Step G of FIG. 1 illustrates the final layer structure 111 obtained after the attachment step of the first embodiment of the inventive method. The final layer structure 111 forms the solar cell assembly SCA. The layer stack 101 forming the CPV cell is attached to the substrate 109 forming the heat sink by the conductive adhesive 110. The final layer structure 111 is characterized in that the side walls of the layer stack 101 are protected against the conductive adhesive 110 by the isolating layer 108.

Thus, during the attachment of the layer stack 101 to the substrate 109, the excess material of the conductive adhesive 110 that overflows from under layer stack 101 so that it at least partially covers the side walls of the layer stack 101 as illustrated in step G of FIG. 1, cannot lead to an electrical shortage between the lower layers of the layer stack 101a, 101b because these layers are electrically isolated from the thermal contact paste 110 via the isolating layer 108.

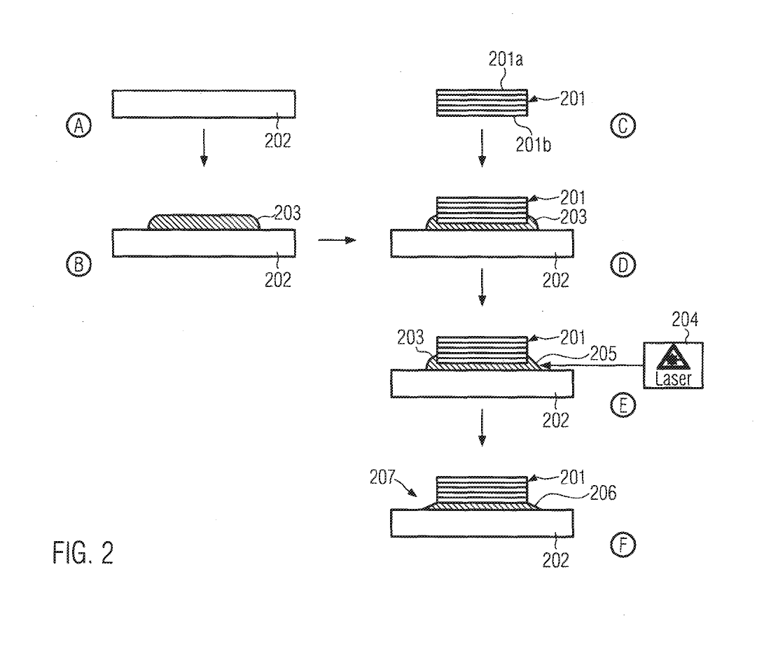

A second embodiment of the inventive method for preventing an electrical shortage between at least two layers of a semiconductor layer stack attached by the surface of one of its layers to a substrate via a conductive adhesive is illustrated in steps A to F of FIG. 2.

According to this embodiment, steps A to D of FIG. 2 illustrate the provision of a semiconductor layer stack 201 comprising two main surfaces 201a, 201b corresponding to the free surfaces of the outermost layers and side walls 201c connecting the two main surfaces 201a, 201b; and the attachment of a substrate 202 to the semiconductor layer stack 201 via a conductive adhesive 203 provided either on one of the main surfaces of the semiconductor layer stack 201 or of the substrate 202 or on both; and steps E to F of FIG. 2 illustrate the removal of excess material of the conductive adhesive 203 from the side walls 201c adjacent to the main surface 201b of the semiconductor layer stack 201 attached to the substrate 202.

In the second embodiment, the semiconductor layer stack 201 can correspond to a thin substrate concentrated photovoltaic (CPV) cell 201, the substrate 202 can be a heat sink, and the conductive adhesive 203 can be silver thermal contact paste.

The second embodiment of the inventive method will be described in more details in the following paragraphs.

Step A of FIG. 2 illustrates the substrate 202 that can play the role of a heat sink and that will be attached to the layer stack 201 illustrated in step C of FIG. 2. As mentioned with respect to the first embodiment, the number of layers comprised in the layer stack 101 and their relative thickness are not necessarily representative of a real thin substrate CPV cell and are only illustrative. Furthermore, reference is made to the properties of the layer stack 101 as illustrated in FIG. 1.

In step B of FIG. 2, the conductive adhesive 203 is provided on the free surface of the heat sink 202 on which the thin substrate CPV cell 201 will be attached. As a variant, the conductive adhesive 203 could also be provided on the layer stack 201 or on both, the layer stack 201 and the substrate 202.

In step D of FIG. 2, the assembly is realized by placing the layer stack 201 on the conductive adhesive 203 to thereby form solar cell assembly with CPV cell and heat sink in the example given above.

During the assembly process of the second embodiment, a surplus of the conductive adhesive 203 used for the attachment of the layer stack 201 to the substrate 202 spills over the edges of the layer stack 201 so that it at least partially covers at least two of its layers on at least one of its side walls 201c, as illustrated in step D of FIG. 2. Thus, an electrical shortage may occur between the junction layers at the lower part of the thin substrate CPV cell 201.

According to the second embodiment, a shortage between the at least two layers of the layer stack 201 that are brought in contact by the surplus of conductive adhesive 203 can be prevented by removing the excess material of the conductive adhesive 203 using a thermal treatment, in particular, by laser ablation. This is illustrated in step E of FIG. 2, where a laser 204 is used for vaporizing the surplus of the conductive adhesive 203 from the lower cell edges.

Laser ablation has the advantage that the surplus of adhesive material 203 can be removed with high precision, while keeping the assembled structure intact. Optimal results can be obtained by adjusting the laser wavelength and power to the adhesive paste 203 material in order to perform the removal as selectively as possible. For removal of the excess material from all sides of the layer stack 101, the stack can again be positioned on a rotation table, like in the first embodiment.

Step F of FIG. 2 illustrates the second embodiment of the inventive method by showing the final structure 207 after the step of removing the surplus of the conductive adhesive 203 and forming a solar cell assembly (SCA). The inventive SCA 207 comprises the layer stack 201 forming the thin substrate CPV cell attached to the substrate 202 forming the heat sink by the conductive adhesive 203, here the silver contact paste, wherein after the laser ablation, the conductive adhesive is provided only between the one main surface 201b of the layer stack 201 and the surface of the substrate 202. Thus, since no conductive contact paste 203 is present on any of the side walls of the layer stack 201, the inventive solar cell assembly 207 of the second embodiment as illustrated in step F of FIG. 2 has the advantage that no electrical shortage can occur due to any surplus of silver paste 203 shortening the bottom junctions of the CPV cell 201.

The first and second embodiments can furthermore be combined. Thus, a deposition of an isolating layer 108 can be accompanied by a laser ablation step.

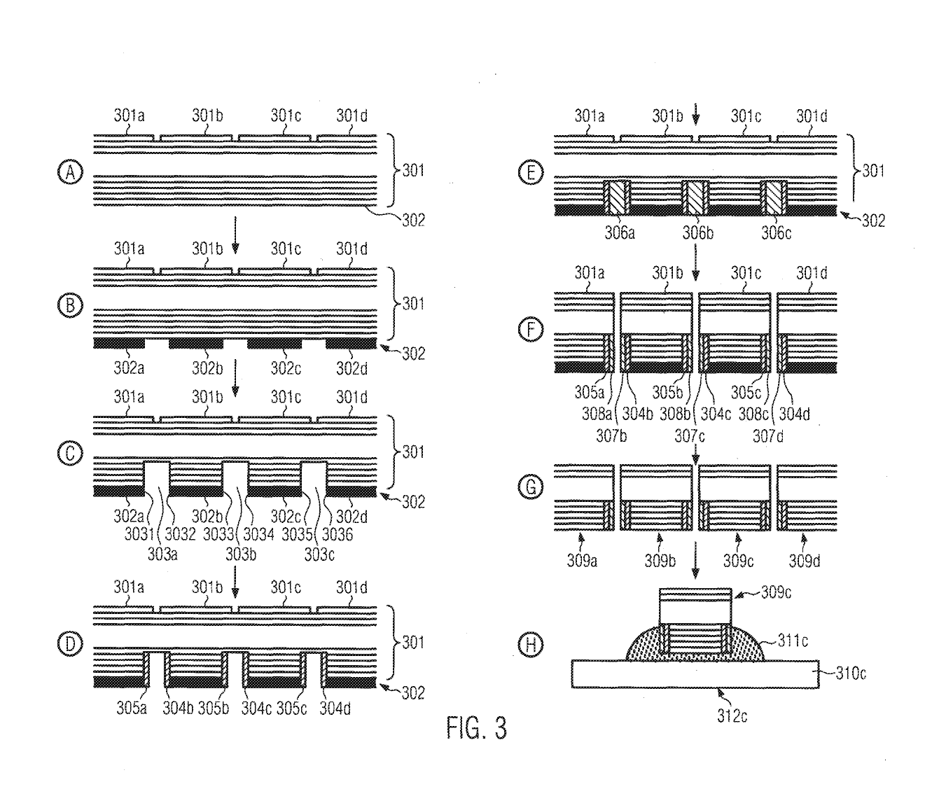

In FIG. 3, the inventive method is described in a third embodiment, comprising steps A to H. According to a variant of the inventive method followed in the third embodiment, step A of FIG. 3 illustrates providing a semiconductor layer stack 301 comprising two main surfaces corresponding to the free surfaces of the outermost layers and side walls connecting the two main surfaces; steps B to G of FIG. 3 illustrate at least partially providing an isolating layer 308a, 308b, 308c, 307b, 307c, 307d on at least one of the side walls 3031, 3032, 3033, 3034, 3035, 3036 of the semiconductor layer stack 301; and step H of FIG. 3 illustrates attaching a substrate 310a, 310b, 310c, 310d to the semiconductor layer stack 309c via a conductive adhesive 311a, 311b, 311c, 311d provided either on one of the main surfaces of the semiconductor layer stack 309c or of the substrate 310a, 310b, 310c, 310d.

In the third embodiment, the semiconductor layer stack is a thin substrate concentrated photovoltaic (CPV) cell wafer 301 from which a plurality of individual thin substrate CPV cells 309a, 309b, 309c, 309d are obtained in subsequent steps of the embodiment. The substrate can be a heat sink 310a, 310b, 310c, 310d, and the conductive adhesive 311a, 311b, 311c, 311d can be a silver thermal contact paste. The third embodiment of the inventive method will be described in more detail in the following paragraphs.

The third embodiment comprises the steps of: providing a semiconductor layer stack as illustrated in step A of FIG. 3, applying an etch mask 302a, 302b, 302c, 302d to the main surface 302 of the semiconductor layer stack 301 that will be attached to the substrate 310a, 310b, 310c, 310d, as illustrated in step B of FIG. 3; at least partially etching into the unmasked area of the masked main surface 302 of the semiconductor layer stack 301 to obtain at least one etched hole 303a, 303b, 303c comprising at least one side wall 3031, 3032, 3033, 3034, 3035, 3036 adjacent to the masked main surface 302 of the semiconductor layer stack 301, as illustrated in step C of FIG. 3; at least partially covering with a passivation material 304b, 304c, 304d, 305a, 305b, 305c the at least one side wall 3031, 3032, 3033, 3034, 3035, 3036 of the at least one etched hole 303a, 303b, 303c adjacent to the masked main surface of the semiconductor layer stack 301, as illustrated in step D of FIG. 3; and at least partially filling with an isolating material 306a, 306b, 306c the at least one etched hole comprising at least one side wall 3031, 3032, 3033, 3034, 3035, 3036 at least partially covered with a passivation material 304b, 304c, 304d, 305a, 305b, 305c and adjacent to the masked main surface 302, as illustrated in step E of FIG. 3.

These steps will be described more in detail in the following paragraphs.

In the third embodiment, the semiconductor layer stack 301 is a thin substrate CPV cell wafer 301 out of which individual thin substrate CPV cells 309a, 309b, 309c, 309d can be produced. The third embodiment of the inventive method has the advantage that the step of isolating the lower edges of the thin substrate CPV cells can be realized during the production of the individual CPV cell from the original wafer, and thus the inventive method can be integrated in the industrial production and assembly processes of thin substrate CPV cells and SCAs.

As illustrated in step A of FIG. 3, the layer stack 301 comprises a plurality of semiconductor layers. The number of layers in the stack depends on the thin substrate CPV cells that are obtained out of the layer stack at the end of the fabrication process. Thus, their number and their relative thicknesses as illustrated in the various steps of FIG. 3 are not necessarily representative of the real thin substrate CPV cells and are only intended for illustrative purposes as already mentioned in the first embodiment.

The layer stack 301 illustrated in step A of FIG. 3 has a first main surface on which at least one of the uppermost layers, here the top layer, has already been processed, such that a plurality of individual elements 301a, 301b, 301c, 301d spaced apart from each other have been obtained. This can be achieved by providing a mask, etching the non-masked areas and removing the mask.

In step B, illustrated in FIG. 3, the etch mask 302, 302b, 302c, 302d is applied on the main surface 302 of the wafer 301 opposite the main surface comprising the individual elements 301a, 301b, 301c, 301d. The etch mask 302a, 302b, 302c, 302d covers a plurality of areas of the layer stack 301 that are essentially opposite to the individual elements 301a, 301b, 301c, 301d on the opposite side of the layer stack. Here, the size of each individual area covered by the mask 302 is smaller compared to one of the individual elements 301a to 301d on the opposite side.

However, the shape and size of the etch masks 302a, 302b, 302c, 302d can be adapted to the needs of the fabrication process and/or the final product. Furthermore, the formation of the individual elements 301a to 301d on the opposite side of the layer stack 301 could also be realized after providing the mask on surface 302.

Step C of FIG. 3 illustrates the subsequent etching step in the third embodiment of the inventive method. The etching, which can be selective and/or anisotropic, leads to the formation of etched holes or trenches 303a, 303b, 303c in the areas not covered by the marks 302a to 302d. At the end of the etching step, the holes have side walls 3031, 3032, 3033, 3034, 3035, 3036 adjacent to the masked areas of the main surface 302.

The depth of the trenches covers a thickness at least equal or superior to the thickness of the two bottom layers of the layer stack 301 toward the masked main surface 302.

The next step of the third embodiment is illustrated in step D of FIG. 3. In this step, the side walls 3031, 3032, 3033, 3034, 3035, 3036 of the etched holes 303a, 303b, 303c are covered with a passivation material 304b, 304c, 304d, 305a, 305b, 305c. The passivation material can be, e.g., one of an oxide or a nitride, such as SiO, SiN, TiO, but is not limited to these materials, and it can be deposited by any suitable technique such as spraying, chemical vapor deposition (CVD) or the like.

Step E of FIG. 3 illustrates the next step of the third embodiment, wherein the etched holes (303a, 303b, 303c) comprising side walls 3031, 3032, 3033, 3034, 3035, 3036 covered with a passivation material 304b, 304c, 304d, 305a, 305b, 305c are at least partially filled with an isolating material 306a, 306b, 306c. The isolating material can be, e.g., an oxide, or any other isolating material suitable in the context of electrically isolating semiconductor materials for solar cells. The filling of the etched holes 303a, 303b, 303c is carried out such that the holes are at least filled up to the limit between the etch masks 302a, 302b, 302c, 302d and the main surface 302 of the layer stack 301 or they can be totally filled as illustrated in step E of FIG. 3.

Subsequently, as illustrated in step F of FIG. 3, the third embodiment further comprises the step of cutting through the layer stack 301 to obtain individual stacks. Cutting is carried out through the at least partially filled at least one etched hole 303a, 303b, 303c and between the individual elements 301a to 301d on the opposite side.

The cutting can, e.g., be realized with a laser or any other means adapted for cutting individual CPV cells 309a, 309b, 309c, 309d from a layer stack 301.

After removal of the etch mask 302a, 302b, 302c, 302d, individual layer stacks 309a, 309b, 309c, 309d are achieved with two main surfaces corresponding to the free surfaces of the outermost layers and side walls 3031, 3032, 3033, 3034, 3035, 3036 connecting the two main surfaces, wherein the side walls 3031, 3032, 3033, 3034, 3035, 3036 are at least partially covered by an isolating layer 307b, 307c, 307d, 308a, 308b, 308c toward the main surface 302 where the attachment will occur. The isolating layer may only be formed of the passivation material 304b, 304c, 304d, 305a, 305b, 305c or, in addition as illustrated in step G, also comprise remaining filling material 307b, 307c, 307d, 308a, 308b, 308c.

Of course, the etch mask removal step may also be carried out before cutting.

Thus, the individual layer stacks 309a, 309b, 309c, 309d forming CPV cells obtained after step G comprise two main surfaces 301a, 301b, 301c, 301d, 302 corresponding to the free surfaces of their outermost layers, and side walls 3031, 3032, 3033, 3034, 3035, 3036 connecting the two main surfaces 301a, 301b, 301c, 301d, 302, which are at least partially covered by an isolating layer, here formed by the passivation material 304b, 304c, 304d, 305a, 305b, 305c and the remaining filling material 307b, 307c, 307d, 308a, 308b, 308c. In particular, the isolating layers cover the side walls 3031, 3032, 3033, 3034, 3035, 3036 toward the lower main surface 302 of the cells 309a, 309b, 309c, 309d over a plurality of layers of the layer stack 309a, 309b, 309c, 309d.

In the next step, the individual layer stacks 309a to 309d are attached to their respective substrate via a conductive adhesive. In this manner, individual CPV cells are connected to their heat sink. Step H of FIG. 3 illustrates one 312c inventive SCAs 312c, obtained in the third embodiment.

The inventive SCAs 312c comprise the layer stack 309c forming the thin substrate CPV cell of the assembly. The layer stack 309c is attached to a substrate 310c forming the heat sink using a conductive adhesive 311c, here a thermal contact paste; here, a silver paste. The individual thin substrate CPV cell 309c is attached to the substrate 312c with the main surface that is adjacent the layers with the isolation layer 313.

During the attachment of the layer stack 309c to the heat sink 310c, the excess of the conductive adhesive 311c provided between the attachment surface of the substrate 310c and the attachment surface of the layer stack 309c may overflow from under the layer stack 309c so that it at least partially covers the side walls of the stack, e.g., at least the two lower layers of the layer stack 309c, as illustrated in step H of FIG. 3.

Since the layer stack 309c comprises the isolating layers with the passivation and filling material 307b, 307c, 307d, 308a, 308b, 308c on the lower part of their side walls 3031, 3032, 3033, 3034, 3035, 3036, covering a thickness at least equal or superior to that of their respective two bottom layers, no electrical shortage can occur between the lower layers of the layer stack 309c toward the main surface 302 attached to the substrate 310c, because these layers are electrically isolated from the thermal contact paste 311c.

Thus, the embodiments and their various variants and combinations can efficiently prevent an electrical shortage between layers of a thin substrate CPV cell when the cell is attached to a heat sink by a conductive adhesive, before or after the assembly process.

What is claimed is:

1. A method for preventing an electrical shortage between at least two layers of a semiconductor layer stack attached by a surface of one layer of the at least two layers to a substrate via a conductive adhesive, the method comprising:
providing a semiconductor layer stack comprising two main surfaces corresponding to free surfaces of outermost layers of the semiconductor layer stack, and at least one side wall connecting the two main surfaces;
attaching a substrate to the semiconductor layer stack via a conductive adhesive provided between one of the two main surfaces of the semiconductor layer stack and the substrate; and
at least partially removing excess material of the conductive adhesive from the at least one side wall adjacent to the one of the main surfaces of the semiconductor layer stack attached to the substrate.

2. The method of claim 1, wherein at least partially removing the excess material of the conductive adhesive comprises using a thermal treatment to at least partially remove the excess material of the conductive adhesive.

3. The method of claim 2, wherein using the thermal treatment to at least partially remove the excess material of the conductive adhesive comprises using a laser ablation technique to at least partially remove the excess material of the conductive adhesive.

4. A method for preventing an electrical shortage between at least two layers of a semiconductor layer stack attached by a surface of one layer of the at least two layers to a substrate via a conductive adhesive, the method comprising:
providing a semiconductor layer stack comprising two main surfaces corresponding to free surfaces of outermost layers of the semiconductor layer stack, and at least one side wall connecting the two main surfaces;
providing an isolating layer on at least a portion of the at least one side wall of the semiconductor layer stack; and
attaching a substrate to the semiconductor layer stack via a conductive adhesive provided between one of the two main surfaces of the semiconductor layer stack and the substrate.

5. The method of claim 4, wherein providing the isolating layer on at least a portion of the at least one side wall of the semiconductor layer stack comprises providing the isolating layer on a portion of the at least one side wall adjacent the one of the two main surfaces of the semiconductor layer stack attached to the substrate.

6. The method of claim 4, further comprising forming the isolating layer to cover a plurality of layers in the semiconductor layer adjacent the one of the two main surfaces of the semiconductor layer stack attached to the substrate.

7. The method of claim 4, wherein providing the isolating layer comprises depositing the isolating layer by thermal spraying.

8. The method of claim 7, wherein depositing the isolating layer by thermal spraying comprising depositing the isolating layer by plasma spraying.

9. The method of claim 4, wherein the semiconductor layer stack comprises a photovoltaic cell.

10. The method of claim 9, wherein the photovoltaic cell comprises a thin substrate concentrated photovoltaic (CPV) cell.

11. The method of claim 10, wherein the substrate comprises a heat sink and the conductive adhesive comprises a thermal contact paste.

12. The method of claim 11, wherein the thermal contact paste comprises a silver paste.

13. The method of claim 4, wherein providing the isolating layer further comprises:
applying an etch mask to the one of the two main surfaces of the semiconductor layer stack to be attached to the substrate;
at least partially etching into an unmasked area of the one of the two main surfaces of the semiconductor layer stack to be attached to the substrate, and forming at least one etched hole;
at least partially covering at least one side wall of the at least one etched hole with a passivation material; and
at least partially filling the at least one etched hole with an isolating material after at least partially covering the at least one side wall of the at least one etched hole with the passivation material.

14. The method of claim 13, further comprising cutting through the at least partially filled at least one etched hole to obtain the at least one semiconductor layer stack having two main surfaces corresponding to free surfaces of outermost layers of the at least one semiconductor layer stack, and at least one side wall connecting the two main surfaces, wherein the isolating layer covers at least a portion of the at least one side wall adjacent the one of the two main surfaces of the semiconductor layer stack to be attached to the substrate.

15. A solar cell assembly, comprising:
a semiconductor layer stack comprising at least a portion of a thin substrate concentrated photovoltaic (CPV) cell, the semiconductor layer stack attached to a heat sink by a thermal contact paste;
wherein the thin substrate CPV cell comprises two main surfaces corresponding to free surfaces of outermost layers of the semiconductor layer stack, and at least one side wall connecting the two main surfaces;
wherein the heat sink comprises at least one free surface; and
wherein the thermal contact paste is provided only between one of the two main surfaces of the semiconductor layer stack and the at least one free surface of the heat sink.
